(19) United States
(12) Patent Application Publication
(10) Pub. No.: US 2025/0150044 A1
(43) Pub. Date: May 8, 2025

(54) RF FRONT-END MODULE AND COMMUNICATION DEVICE

(71) Applicant: RADROCK (SHENZHEN) TECHNOLOGY CO., LTD., Shenzhen (CN)

(72) Inventors: Lan Nan, Shenzhen (CN); Jianxing Ni, Shenzhen (CN)

(21) Appl. No.: 19/001,450

(22) Filed: Dec. 25, 2024

(30) Foreign Application Priority Data
Nov. 3, 2023 (CN) 202311459819.X

(51) Int. Cl. H03F 3/21; H03F 3/213

(52) U.S. Cl. CPC H03F 3/211; H03F 3/213; H03F 2200/451; H03F 2200/541

(57) ABSTRACT

The application discloses an RF front-end module, including a substrate, and a first power amplification unit and a second power amplification unit arranged on the substrate; the first power amplification unit comprises a first amplification chip and a first transformer connected with the first amplification chip; the second power amplification unit comprises a second amplification chip and a second transformer connected with the second amplification chip; the first amplification chip and the first transformer are sequentially arranged along a first direction, and the second amplification chip and the second transformer are sequentially arranged along a second direction; and a first virtual straight line extending along the first direction and a second virtual straight line extending along the second direction intersect each other. The application addresses signal crosstalk between the first and second power amplification units, improving isolation and enhancing the quality of the first and second power amplification units.

### CROSS REFERENCE TO RELATED APPLICATIONS

The present application claims the benefit of Chinese Patent Application No. 202311459819X filed on Nov. 3, 2023, the contents of which are incorporated herein by reference in their entirety.

### TECHNICAL FIELD

The application relates to the technical field of radio frequency (RF), in particular to an RF front-end module and a communication device.

### BACKGROUND

As science and technology advance, new frequency bands of RF signals emerge. Different amplification modules are typically used to amplify RF signals of various frequency bands. However, in the design process of an RF front-end module, in order to achieve the design requirements of miniaturization and integration, isolation degree between different amplification modules is frequently weak, affecting the output quality of the RF signal.

### SUMMARY OF THE INVENTION

The embodiments of the application provide an RF front-end module, aiming at addressing the issue of poor isolation degree between different amplification modules for the RF front-end module.

The embodiment of the application provides an RF front-end module, comprising: a substrate, and a first power amplification unit and a second power amplification unit arranged on the substrate; the first power amplification unit comprises a first amplification chip and a first transformer connected with the first amplification chip; the second power amplification unit comprises a second amplification chip and a second transformer connected with the second amplification chip; the first amplification chip and the first transformer are sequentially arranged along a first direction, and the second amplification chip and the second transformer are sequentially arranged along a second direction; and a first virtual straight line extending along the first direction and a second virtual straight line extending along the second direction intersect each other.

Further, the first virtual straight line and the second virtual straight line intersect at point O, and an angle range formed by a first virtual straight line segment extending along the first direction at point O and a second virtual straight line segment extending along the second direction at point O is [90°, 180°].

Further, the first virtual straight line and the second virtual straight line intersect at an angle of 90°.

Further, the first transformer is arranged adjacent to a first side edge of the first amplification chip, and an extension direction of the first side edge of the first amplification chip is the first direction; the second transformer is arranged adjacent to a second side edge of the second amplification chip, and an extension direction of the second side edge of the second amplification chip is the second direction; the first direction and the second direction intersect.

Further, the first transformer is arranged on a side of the first amplification chip away from the second power amplification unit, and/or, the second transformer is arranged on a side of the second amplification chip away from the first power amplification unit.

Further, the RF front-end module further comprises a control chip, and the control chip is arranged between the first amplification chip and the second amplification chip.

Further, the first amplification chip comprises a first RF amplification circuit, and the first RF amplification circuit is used for amplifying an RF signal of a first frequency band; the second amplification chip comprises a second RF amplification circuit, and the second RF amplification circuit is used for amplifying an RF signal of a second frequency band; the first frequency band and the second frequency band are different frequency bands.

Further, the substrate comprises M first signal input ends and N second signal input ends, the M first signal inputs end and the N second signal input ends are arranged on a fourth side edge of the substrate, and the fourth side edge is arranged along the second direction; the first signal input end is used for inputting the RF signal of the first frequency band, and the second signal input end is used for inputting the RF signal of the second frequency band; the first amplification chip is arranged in an area close to the first signal input end, and the second amplification chip is arranged in an area close to the second signal input end.

Further, the first amplification chip comprises a first output pin, the first output pin is connected with the first transformer and arranged on the first side edge of the first amplification chip, and the first side edge of the first amplification chip is arranged along the first direction and adjacent to the first transformer; the second amplification chip comprises a second output pin, the second output pin is connected with the second transformer and arranged on the second side edge of the second amplification chip, and the second side edge of the second amplification chip is arranged along the second direction and adjacent to the second transformer.

Further, the first amplification chip comprises a first input pin, and the first input pin is arranged on a third side edge of the first amplification chip, and the third side edge of the first amplification chip is arranged along the first direction and adjacent to the second amplification chip; the second amplification chip comprises a second input pin, the second input pin is arranged on a fourth side edge of the second amplification chip, and the fourth side edge of the second amplification chip is arranged along the second direction and adjacent to the second signal input end.

Further, the RF front-end module further comprises a first switch chip and a second switch chip, and the first switch chip is connected with an output end of the first transformer, the second switch chip is connected with an output end of the second transformer; the first switch chip is arranged in a second side area of the first transformer, and the second side area of the first transformer is arranged along the second direction and adjacent to the output end of the first transformer; the second switch chip is arranged in a second side area of the second transformer, and the second side area of the second transformer is arranged along the second direction and adjacent to the output end of the second transformer.

Further, the first RF amplification circuit is a first differential amplification circuit, and the second RF amplification circuit is a second differential amplification circuit.

Further, the RF signal of the first frequency band and the RF signal of the second frequency band are signals specified in a same mobile communication standard.

Further, the first power amplification unit and the second power amplification unit are configured to support transmission of dual-connectivity RF signals.

Further, the RF front-end module is configured to support simultaneous transmission of RF signals by the first power amplification unit and the second power amplification unit.

Further, the angle range formed by the intersection of the first virtual straight line and the second virtual straight line is at least one of [90°, 120°], (120°, 130°], (130°, 150°], (150°, 160°], (160°, 175°] or (175°, 180°].

Further, an RF front-end module is provided, comprising: a substrate, and a first power amplification unit and a second power amplification unit arranged on the substrate;

the first power amplification unit comprises a first amplification chip and a first transformer connected with the first amplification chip;

the second power amplification unit comprises a second amplification chip and a second transformer connected with the second amplification chip;

the first transformer is arranged adjacent to a first side edge of the first amplification chip, and the first side edge of the first amplification chip is arranged along a first direction; the second transformer is arranged adjacent to a second side edge of the second amplification chip, and the second side edge of the second amplification chip is arranged along a second direction; and

the first power amplification unit and the second power amplification unit are configured to support transmission of dual-connectivity RF signals.

A communication device, comprises the RF front-end module described above.

In this embodiment, the RF front-end module includes a substrate, and a first power amplification unit and a second power amplification unit arranged on the substrate; the first power amplification unit comprises a first amplification chip and a first transformer connected with the first amplification chip; the second power amplification unit comprises a second amplification chip and a second transformer connected with the second amplification chip; the first amplification chip and the first transformer are sequentially arranged along the first direction, and the second amplification chip and the second transformer are sequentially arranged along the second direction; and the first virtual straight line extending along the first direction and the second virtual straight line extending along the second direction intersect. In this embodiment, the first amplification chip and the first transformer are not arranged in parallel with the second amplification chip and the second transformer along the same direction, allowing the distance between the first transformer and the second transformer to be increased. This ameliorates the problem of signal crosstalk between the first RF signal transmitted by the first power amplification unit and the second RF signal transmitted by the second power amplification unit, and prevents mutual inductance between the first transformer 12 and the second transformer 22 due to being too close, improves the isolation degree between the first power amplification unit and the second power amplification unit. In this way, while ensuring the integration and occupied area of the RF front-end module, the overall performance (such as sensitivity) of the RF front-end module is optimized, and the quality of RF signals output by the RF front-end module is improved.

### BRIEF DESCRIPTION OF THE DRAWINGS

In order to explain the technical solution of the embodiments of this application more clearly, the drawings described in the description of the embodiments of this application will be briefly introduced below. Obviously, the drawings in the present application and their accompanying detailed description are directed to merely exemplary embodiments of the application. For those of ordinary skill in this field, other drawings may be obtained according to these drawings without any creative effort.

FIG. 1 is a structural schematic diagram of an RF front-end module provided by the present application.

FIG. 2 is another structural schematic diagram of the RF front-end module provided by the present application.

FIG. 3 is another structural schematic diagram of the RF front-end module provided by the present application.

FIG. 4 is another structural schematic diagram of the RF front-end module provided by the present application.

FIG. 5 is another structural schematic diagram of the RF front-end module provided by the present application.

FIG. 6 is another structural schematic diagram of the RF front-end module provided by the present application.

### DETAILED DESCRIPTION OF PREFERRED EMBODIMENTS

For a better understanding to those skilled in the art, the technical solutions in the embodiments of the present application will be clearly and completely described below with reference to the drawings in the embodiments of this application. Obviously, the described embodiments are merely part of the embodiments of this application, not all of them. Based on the embodiments in this application, all other embodiments obtained by those of ordinary skill in the art without creative effort belong to the protection scope of this application.

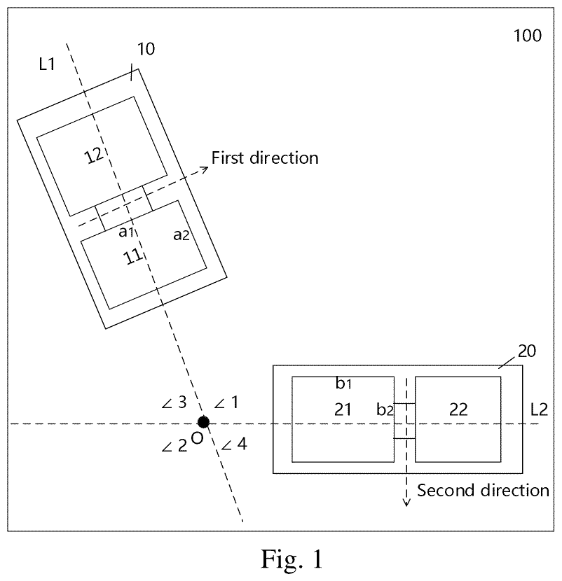

Please refer to FIG. 1, the first embodiment of the present application provides an RF front-end module, which is an element that integrates two or more discrete devices such as RF switch, low noise amplifier, filter, duplexer and power amplifier into a separate module. This improves the integration and hardware performance, and miniaturizes the volume. Specifically, the RF front-end module can be applied to communication devices such as smart phones, tablet computers, smart watches, etc. The RF front-end module can work in any working frequency bands, such as 2G, 3G, 4G, 5G or WIFI.

In at least one embodiment, the RF front-end module can support modules of 4G (Fourth Generation Mobile Communication) standard, 5G (Fifth Generation Mobile Communication) standard, etc. The 4G standard is, for example, 3GPP (Third Generation Partnership Project) LTE (Long Term Evolution) standard. The 5G standard is, for example, 5G NR (New Radio). The RF front-end module in this embodiment is a module that can support Carrier Aggregation and Dual Connectivity. Carrier aggregation and dual connectivity refer to the communication using radio waves of multiple frequency bands at the same time. For example, the RF front-end module can simultaneously support the communication of signals in the frequency band specified by 4G and signals in another frequency band specified by 4G. Or, the RF front-end module can simultaneously support the communication of signals in the frequency band specified by 4G and signals in another frequency band specified by 5G.

The application provides an RF front-end module, as shown in FIG. 1 below, which includes a substrate 100, and a first power amplification unit 10 and a second power amplification unit 20 arranged on the substrate 100. The first power amplification unit 10 includes a first amplification chip 11 and a first transformer 12 connected to the first amplification chip 11. The second power amplification unit 20 includes a second amplification chip 21 and a second transformer 22 connected to the second amplification chip 21. The first amplification chip 11 and the first transformer 12 are sequentially arranged along a first direction, and the second amplification chip 21 and the second transformer 22 are sequentially arranged along a second direction. A first virtual straight line L1 extending along the first direction and a second virtual straight line L2 extending along the second direction intersect each other.

In at least one embodiment, the first amplification chip 11 is a chip integrated with a first power amplification circuit. The first power amplifier circuit may be any types of amplifier circuits such as a single-ended amplification circuit, a differential amplification circuit, and a Doherty amplifier circuit. Similarly, the second amplification chip 21 is a chip integrated with a second power amplification circuit. The second power amplifier circuit may be any types of amplifier circuits, such as single-ended amplification circuit, a differential amplification circuit, and a Doherty amplifier circuit, etc. In this embodiment, the types of the first RF amplification circuit and the second RF amplification circuit are not specifically limited.

In at least one embodiment, the first power amplification unit 10 and the second power amplification unit 20 are units for amplifying RF signals of different frequency bands. In this embodiment, the range of the frequency band of the amplified RF signals corresponding to the first power amplification unit 10 and the range of the frequency band of the amplified RF signals corresponding to the second power amplification unit 20 are not specifically limited.

In at least one embodiment, the first transformer 12 may be connected to an output end of the first amplification chip 11 or connected to an input end of the first amplification chip 11. The second transformer 22 may be connected to an output end of the second amplification chip 21 or connected to an input end of the second amplification chip 21.

In at least one embodiment, the first transformer 12 may be a single-ended-to-differential transformer, a differential-to-single-ended transformer, a single-ended-to-single-ended transformer, and a differential-to-differential transformer. Similarly, the second transformer 22 may be a single-ended-to-differential transformer, a differential-to-single-ended transformer, a single-ended-to-single-ended transformer, and differential-to-differential transformer. This embodiment does not specifically define the types and specific implementations of the first transformer and the second transformer.

In at least one embodiment, because both the first power amplification unit 10 and the second power amplification unit 20 are integrated on one substrate, and in order to ensure the integration of the RF front-end module, the first power amplification unit 10 and the second power amplification unit 20 need to be arranged adjacent to each other. However, this will lead to signal crosstalk between the first RF signal transmitted by the first power amplification unit 10 and the second RF signal transmitted by the second power amplification unit 20. Signal crosstalk will cause the first RF signal and the second RF signal to produce IMD noise. When the IMD noise happens to fall into a certain receiving frequency band, it will lead to de-sensitivity of the receiving channel. Moreover, because the first transformer 12 and the second transformer 22 are electromagnetic devices, mutual inductance is easy to occur when they are too close. In view of this, in this embodiment, the first amplification chip 11 and the first transformer 12 in the first power amplification unit 10 are sequentially arranged along the first direction, and the second amplification chip 21 and the second transformer 22 are sequentially arranged along the second direction. The first virtual straight line L1 extending along the first direction and the second virtual straight line L2 extending along the second direction intersect. That is, the first amplification chip 11 and the first transformer 12 are not arranged in parallel with the second amplification chip 21 and the second transformer 22 in the same direction, allowing the distance between the first transformer and the second transformer to be increased. This ameliorates the problem of signal crosstalk between the first RF signal transmitted by the first power amplification unit 10 and the second RF signal transmitted by the second power amplification unit 20, and prevents mutual inductance between the first transformer 12 and the second transformer 22 due to their proximity, improves the isolation degree between the first power amplification unit 10 and the second power amplification unit 20.

In at least one embodiment, the first virtual straight line L1 is a virtual straight line passing through the center point of the first amplification chip and the coupling center point of the first transformer. The second virtual straight line L2 is a virtual straight line passing through the center point of the second amplification chip and the coupling center point of the second transformer. The first transformer includes a first winding and a second winding which are coupled with each other, and the coupling center point of the first transformer is the midpoint of the area formed by the first winding and second winding. The second transformer includes a third winding and a fourth winding which are coupled with each other, and the coupling center point of the second transformer is the midpoint of the area formed by third winding and fourth winding.

In at least one embodiment, the extension direction of the first virtual straight line L1 is the same as that of the second side edge a2 of the first amplification chip 11; the extension direction of the second virtual straight line L2 is the same as that of the first side edge b1 of the second amplification chip 21.

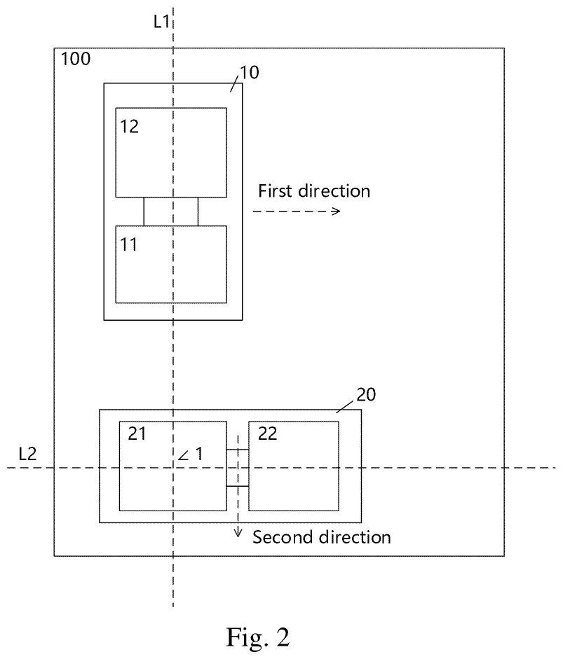

The intersection angle between the first virtual straight line L1 and the second virtual straight line L2 may be any angle. For example, referring to FIG. 1 below, the intersection angle between the first virtual straight line L1 and the second virtual straight line L2 is greater than 90°, for example, ∠1 shown in FIG. 1. Alternatively, as shown in FIG. 2 below, the intersection angle between the first virtual straight line L1 and the second virtual straight line L2 is equal to 90°, for example, ∠1 as shown in FIG. 2. Compared with the layout that the first amplification chip 11 and the first transformer 12 are arranged in parallel with the second amplification chip 21 and the second transformer 22 in the same direction, this allows the distance between the first transformer and the second transformer to be larger, and prevents the mutual inductance between the first transformer 12 and the second transformer 22 due to being too close. Thereby improving the isolation degree between the first power amplification unit 10 and the second power amplification unit 20, and ameliorating the signal interference between RF signals of different frequency bands.

In this embodiment, the RF front-end module includes a substrate, and a first power amplification unit and a second power amplification unit arranged on the substrate. The first power amplification unit comprises a first amplification chip and a first transformer connected with the first amplification chip. The second power amplification unit comprises a second amplification chip and a second transformer connected with the second amplification chip. The first amplification chip and the first transformer are sequentially arranged along a first direction, and the second amplification chip and the second transformer are sequentially arranged along a second direction. A first virtual straight line extending along the first direction and a second virtual straight line extending along the second direction intersect. In this embodiment, the first amplification chip 11 and the first transformer 12 are not arranged in parallel with the second amplification chip 21 and the second transformer 22 along the same direction, so that the distance between the first transformer and the second transformer can be increased. This ameliorates the problem of signal crosstalk between the first RF signal transmitted by the first power amplification unit 10 and the second RF signal transmitted by the second power amplification unit 20, and prevents mutual inductance between the first transformer 12 and the second transformer 22 due to their proximity, improves the isolation degree between the first power amplification unit 10 and the second power amplification unit 20. In this way, while ensuring the integration and occupied area of the RF front-end module, the overall performance (such as sensitivity) of the RF front-end module is optimized, and the quality of RF signals output by the RF front-end module is improved.

In a specific embodiment, the first virtual straight line and the second virtual straight line intersect at point O, and an angle range formed by a first virtual straight line segment extending along the first direction at point O and a second virtual straight line segment extending along the second direction at point O is [90°, 180°].

In at least one embodiment, referring to FIG. 1 below, the first virtual straight line passes through the center point of the first amplification chip and the coupling center point of the first transformer. The second virtual straight line passes through the center point of the second amplification chip and the coupling center point of the second transformer. The first virtual straight line and the second virtual straight line intersect at point O. That is, the first virtual straight line and the second virtual straight line can form four angles, which are ∠1, ∠2, ∠3 and ∠4. In this embodiment, the angle range (∠1) formed by the first virtual straight line segment extending along the first direction at point O and the second virtual straight line segment extending along the second direction at point O is [90°, 180°]. For example, the angle (∠1) formed by the first virtual straight line segment extending along the first direction at point O and the second virtual straight line segment extending along the second direction at point O is 120°, 130°, 150°, 160° or 175°, etc. In this way, the spacing between the first transformer 12 and the second transformer 22 can be further increased. Thus the problem of signal interference between RF signals of different frequency bands can be further ameliorated, and mutual inductance between the first transformer 12 and the second transformer 22 due to their proximity can be avoided. Therefore, while ensuring the integration and occupied area of the RF front-end module, the overall performance of the RF front-end module is optimized, and the quality of RF signals output by the RF front-end module is improved.

In a specific embodiment, the first virtual straight line and the second virtual straight line intersect at an angle of 90°.

In at least one embodiment, as shown in FIG. 2 below, due to the limited area on the substrate, while considering increasing the spacing between the first transformer 12 and the second transformer 22 to address the signal interference between signals, it is also necessary to consider the reasonable layout of each unit and module on the substrate to maximize the area utilization rate of the substrate. In this embodiment, the angle at which the first virtual straight line and the second virtual straight line intersect is 90°. For example, the first amplification chip and the first transformer are sequentially arranged along the horizontal direction, and the second amplification chip and the second transformer are arranged along the vertical direction. Or, the first amplification chip and the first transformer are sequentially arranged along the vertical direction, and the second amplification chip and the second transformer are arranged along the horizontal direction. In this way, while alleviating the signal interference between RF signals of different frequency bands, the layout of each module on the substrate can be reasonably optimized, and the area utilization rate of the substrate can be improved.

In a specific embodiment, as shown in FIGS. 1 and 2 below, the first transformer 12 is arranged adjacent to the first side edge of the first amplification chip 11, and the extension direction of the first side edge of the first amplification chip 11 is the first direction; the second transformer 22 is arranged adjacent to the second side edge of the second amplification chip 21, and the extension direction of the second side edge of the second amplification chip 21 is the second direction; the first direction and the second direction intersect.

Referring to FIG. 1 below, the first transformer 12 is arranged adjacent to the first side edge al of the first amplification chip 11, and the extension direction of the first side edge al of the first amplification chip 11 is the first direction. The second transformer 22 is adjacent to the second side edge b2 of the second amplification chip 21, and the extension direction of the second side edge b2 of the second amplification chip 21 is the second direction. Optionally, the first direction is vertical and the second direction is horizontal. Or the first direction is horizontal and the second direction is vertical. The second direction intersects the first direction. For example, the horizontal direction may be the length direction of the substrate and the vertical direction may be the width direction of the substrate. It should be noted that the horizontal direction and the vertical direction in this embodiment include but are not limited to being perpendicular to each other, i.e., the intersection angle of the first direction and the second direction includes but is not limited to 90°. For example, the intersection angle between the first direction and the second direction mat also be 80°, 100°, 120°, 130°, etc., as long as the first direction and the second direction intersect each other.

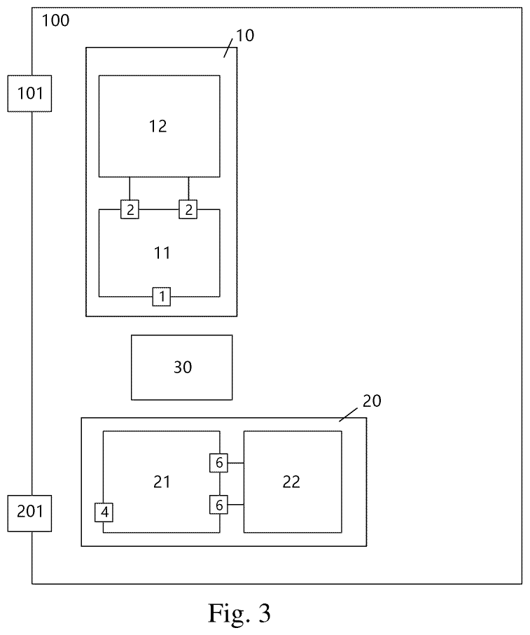

As a specific embodiment, referring to FIG. 3 below, this embodiment is exemplified by taking the horizontal direction of the substrate as the first direction and the vertical direction of the substrate as the second direction. The first transformer 12 is arranged on a first side area of the first amplification chip 11, and the first side edge of the first amplification chip 11 is arranged along the horizontal direction of the substrate. The first side edge of the first amplification chip 11 may be along the upper side and the lower side of the first amplification chip 11 in the horizontal direction of the substrate. The second transformer 22 is arranged on a second side area of the second amplification chip 21, and the second side edge of the second amplification chip 21 is arranged along the vertical direction of the substrate. The second side edge of the second amplification chip 21 may be the left side and the right side of the second amplification chip 11 in the vertical direction of the substrate. Preferably, in order to further increase the spacing between the first transformer 12 and the second transformer 22, in this embodiment, the first transformer 12 is arranged on the upper side of the first amplification chip 11 in the horizontal direction of the substrate. The second transformer 22 is arranged on the right side of the second amplification chip 21 in the vertical direction of the substrate. This alleviates the signal interference between RF signals of different frequency bands.

In a specific embodiment, the first transformer is arranged on a side of the first amplification chip away from the second power amplification unit, and/or the second transformer is arranged on a side of the second amplification chip away from the first power amplification unit.

In at least one embodiment, the first amplification chip and the first transformer are sequentially arranged along the first direction, and the second amplification chip and the second transformer are sequentially arranged along the second direction; the first transformer is arranged on a side of the first amplification chip away from the second power amplification unit, and/or the second transformer is arranged on a side of the second amplification chip away from the first power amplification unit. For example, the first transformer 12 is arranged on the upper side of the first amplification chip 11 in the horizontal direction of the substrate, the second transformer 22 is arranged on the right side of the second amplification chip 21 in the vertical direction of the substrate. This allows the spacing between the first transformer 12 and the second transformer 22 to be further increased, thus preventing mutual inductance between the first transformer 12 and the second transformer 22 due to being too close, improving the signal interference between RF signals of different frequency bands. Therefore, while ensuring the integration and occupied area of the RF front-end module, the overall performance of the RF front-end module is optimized, and the quality of RF signals output by the RF front-end module is improved.

In a specific embodiment, as shown in FIG. 3 below, the RF front-end module further includes a control chip 30, which is arranged between the first amplification chip and the second amplification chip.

In at least one embodiment, by arranging the control chip 30 between the first amplification chip 11 and the second amplification chip 21, the signal transmission path between the control chip 30 and the first amplification chip 11/second amplification chip 21 can be optimized, thereby facilitating the control of the first amplification chip 11 and the second amplification chip 21 by the control chip 30.

As an example, the control chip obtains control commands from communication equipment through MIPI communication bus (Mobile Industry Processor Interface). That is, control commands are obtained from communication equipment through VIO, SCLK and SDATA pins, so as to control the working states of the first RF amplification circuit in the first amplification chip 11 and the second RF amplification circuit in the second amplification chip 21. Optionally, the control chip is a CMOS (Complementary Metal Oxide Semiconductor) chip, i.e., the control chip is realized by CMOS (Complementary Metal Oxide Semiconductor) manufacturing technology.

In a specific embodiment, the first amplification chip 11 includes a first RF amplification circuit for amplifying the RF signal of the first frequency band; the second amplification chip 21 includes a second RF amplification circuit for amplifying the RF signal of the second frequency band.

In at least one embodiment, the first frequency band may be a medium frequency band and the second frequency band may be a high frequency band. The range of the first frequency band is 1710 MHz-1980 MHz, and the range of the second frequency band is 2300 MHz-2690 MHz. Alternatively, the first frequency band may be a low frequency band and the second frequency band may be a medium frequency band. The range of the first frequency band is 663 MHz-915 MHZ, and the range of the second frequency band is 1710 MHZ-1980 MHz. It should be noted that the first frequency band can be divided into a plurality of different first frequency sub-bands, and the second frequency band can be divided into a plurality of different second frequency sub-bands. This embodiment does not specifically limit the frequency band range of the first frequency band and the frequency band range of the second frequency band.

In at least one embodiment, the first RF amplification circuit in the first amplification chip 11 and the second RF amplification circuit in the second amplification chip 21 are used to amplify RF signals of different frequency bands, which not only can improve the integration of RF front-end module, but also can process broadband signals, making the application range of RF front-end module wider.

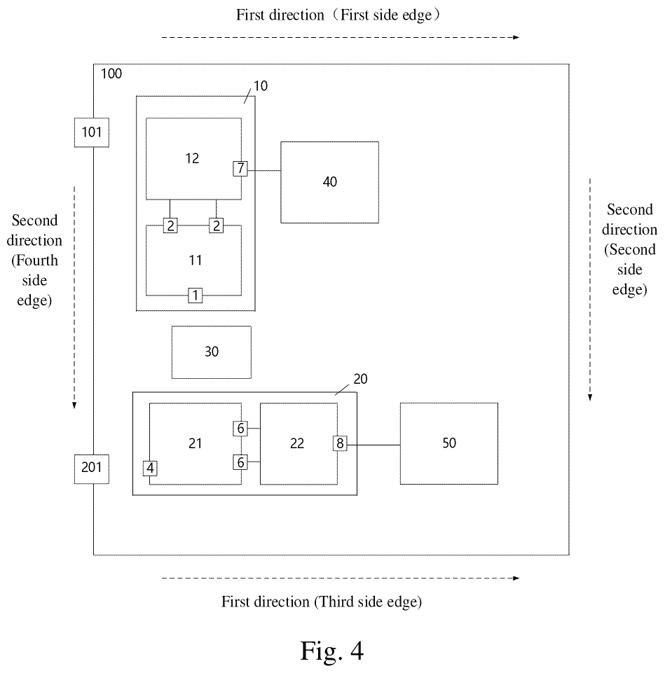

In a specific embodiment, as shown in FIG. 4 below, the substrate 100 includes M first signal input ends 101 and N second signal input ends 201. The M first signal input ends and the N second signal input ends are arranged on the fourth side edge of the substrate, and the fourth side edge is arranged along the second direction. The first signal input end 101 is used for inputting the RF signal of the first frequency band and the second signal input end 201 is used for inputting the RF signal of the second frequency band. The first amplification chip 11 is positioned near the first signal input end, and the second amplification chip 21 is positioned near the second signal input end.

M and N are positive integers. For example, the number M of the first signal input end is 2, 3, 4 or 5, etc. The number N of second signal input end is 2, 3, 4 or 5, etc. Different first signal inputs end can be used to input RF signals of different sub-frequency bands in the first frequency band, and different second signal input end can be used to input RF signals of different sub-frequency bands in the second frequency band. Optionally, the number M of first signal input end and the number N of second signal input end may be the same or different. The M first signal input ends and the N second signal input ends are arranged on the fourth side edge of the substrate, and the fourth side edge is arranged along the second direction. The second direction may be horizontal or vertical. This embodiment takes the second direction as the vertical direction of the substrate and the vertical direction as the width direction of the substrate as an example, that is, the M first signal input ends and the N second signal input ends are all arranged on the same side of the vertical direction of the substrate (for example, the left side of the vertical direction of the substrate).

In at least one embodiment, the first amplification chip 11 is connected with at least one of the M first signal input ends, and the second amplification chip 21 is connected with at least one of the N second signal input ends 201. The RF signal of the first frequency band input from the first signal input end is transmitted to the first amplification chip 11 for amplification, and the RF signal of the second frequency band input from the second signal input end is transmitted to the second amplification chip 21 for amplification.

In at least one embodiment, the RF signal of the first frequency band input from the first signal input end needs to be transmitted to the first amplification chip 11 for amplification, and the RF signal of the second frequency band input from the second signal input end needs to be transmitted to the second amplification chip 21 for amplification, therefore, in this embodiment, the first amplification chip 11 is arranged near the first signal input end, and the second amplification chip 21 is arranged near the second signal input end. In this way, the signal transmission path between the first signal input end and the first amplification chip 11 and the signal transmission path between the second signal input end and the second amplification chip 21 can be optimized, thereby reducing the signal traces on the substrate and optimizing the overall layout of the RF front-end module.

In a specific embodiment, the first amplification chip includes a first output pin, which is connected with the first transformer and arranged on the first side edge of the first amplification chip, and first side edge of the first amplification chip is arranged along the first direction and adjacent to the first transformer. The second amplification chip includes a second output pin, which is connected with the second transformer and arranged on the second side edge of the second amplification chip, and the second side edge of the second amplification chip is arranged along the second direction and adjacent to the second transformer.

In at least one embodiment, there may be one or more first output pins, and one or more second output pins. The first output pin of the first amplification chip is connected with the first transformer 12, and the second output pin of the second amplification chip is connected with the second transformer 22. Specifically, the first output pin of the first amplification chip may be connected with the first transformer through, but not limited to, a first bonding wire, and the second output pin of the second amplification chip may be connected with the first transformer through, but not limited to, a second bonding wire. The number of the bonding wires may be one or more, and the number of the second bonding wires may be one or more.

In at least one embodiment, the first direction is vertical and the second direction is horizontal, or the first direction is horizontal and the second direction is vertical. Where the second direction intersects the first direction. For example, the horizontal direction may be the length direction of the substrate and the vertical direction may be the width direction of the substrate.

In at least one embodiment, the horizontal direction of the substrate is the first direction, and the vertical direction of the substrate is the second direction. Specifically, the first output pin is used to output the RF amplified signal amplified by the first RF amplification circuit in the first amplification chip. The first amplification chip comprises a first output pin which is connected with the first transformer 12. The two first output pins 2 shown in FIG. 4 are connected with the first transformer 12. That is, the RF amplified signal amplified by the first RF amplification circuit in the first amplification chip is transmitted to the first transformer 12 through the first output pin. In this embodiment, the first output pin is arranged on the first side edge of the first amplification chip, and the first side edge of the first amplification chip is arranged along the first direction and adjacent to the first transformer. For example, the first output pin is arranged on the upper side of the first amplification chip arranged along the first direction, so that the signal transmission path between the first output pin of the first amplification chip and the first transformer can be optimized, the signal traces on the substrate can be reduced, and the overall layout of the RF front-end module can be optimized.

In at least one embodiment, the horizontal direction of the substrate is the first direction, and the vertical direction of the substrate is the second direction. Specifically, the second output pin is used to output the RF amplified signal amplified by the second RF amplification circuit in the second amplification chip. The second amplification chip includes a second output pin, which is connected with the second transformer 22. The second output pins 6 shown in FIG. 4 are connected with the second transformer 22. That is, the RF amplified signal amplified by the second RF amplification circuit in the second amplification chip is transmitted to the second transformer 22 through the second output pin. In this embodiment, the second output pin is arranged on the second side edge of the second amplification chip 21, and the second side edge of the second amplification chip is arranged along the second direction and adjacent to the second transformer 22. For example, the second output pin is arranged on the right side of the first amplification chip arranged along the second direction. This can optimize the signal transmission path between the second output pin of the second amplification chip and the second transformer, reduce the signal traces on the substrate, and further optimize the overall layout of the RF front-end module.

In a specific embodiment, as shown in FIG. 4 below, the first amplification chip includes a first input pin 1, which is arranged on the third side edge of the first amplification chip, and the third side edge of the first amplification chip is arranged along the first direction and adjacent to the second amplification chip. The second amplification chip comprises a second input pin 4, the second input pin 4 is arranged on the fourth side edge of the second amplification chip 21, and the fourth side edge of the second amplification chip 21 is arranged along the second direction and adjacent to the second signal input end 201.

In at least one embodiment, there may be one or more first input pins, and one or more second input pins. The first input pin of the first amplification chip is directly or indirectly connected to the first signal input end 101 (e.g., through other components or circuits), and the second input pin of the second amplification chip is directly or indirectly connected to the second signal input end 201 (e.g., through other components or circuits). Specifically, the first input pin of the first amplification chip may be connected with the first signal input end 101 through, but not limited to, a third bonding wire, and the second input pin of the second amplification chip may be connected with the second signal input end 201 through, but not limited to, a fourth bonding wire. The number of the third bonding wires may be one or more, and the number of the fourth bonding wires may be one or more.

In at least one embodiment, the horizontal direction of the substrate is the first direction, and the vertical direction of the substrate is the second direction. Specifically, the first RF signal input from the first signal input end 101 needs to be transmitted to the first amplification chip through the first input pin for amplification. The second RF signal input from the second signal input end 201 needs to be transmitted to the second amplification chip through the second input pin for amplification. The M first signal input ends and the N second signal input ends in this embodiment are all arranged on the same side of the substrate (i.e., the fourth side edge of the substrate, which is arranged along the second direction). In this embodiment, the first input pin is arranged on the third side edge of the first amplification chip, and the third side edge of the first amplification chip is arranged along the first direction and adjacent to the second amplification chip. The second amplification chip comprises a second input pin, and the second input pin is arranged on the fourth side edge of the second amplification chip, and the fourth side edge of the second amplification chip is arranged along the second direction and adjacent to the second signal input end. In this way, while alleviating the signal interference between RF signals of different frequency bands, the signal transmission path between the first amplification chip and the first signal input end, and the signal transmission path between the second amplification chip and the second signal input end can be optimized, thereby reducing the signal traces on the substrate and further optimizing the overall layout of the RF front-end module.

In a specific embodiment, the RF front-end module further comprises a first switch chip 40 and a second switch chip 50. The first switch chip 40 is connected with the output end of the first transformer, the second switch chip is connected with the output end of the second transformer. The first switch chip 40 is arranged in a second side area of the first transformer 12, and the second side area of the first transformer 12 is arranged along the second direction and adjacent to the output end of the first transformer 12. The second switch chip 50 is arranged in a second side area of the second transformer 22, and the second side area of the second transformer 22 is arranged along the second direction and adjacent to the output end of the second transformer 22.

The first switch chip 40 and the second switch chip 50 are bare chips integrated with at least one switching device. The first switch chip 40 and the second switch chip 50 may be chips realized by any manufacturing process in the prior art. As an example, the first switch chip 40 and the second switch chip 50 are SOI (Silicon-On-Insulator) chips. That is, the first switch chip 40 and the second switch chip 50 are made using SOI (Silicon-On-Insulator) manufacturing technology.

In at least one embodiment, the first RF amplified signal output by the first transformer is output through the first switch chip, and the second RF amplified signal output by the second transformer is output through the second switch chip. This embodiment takes the horizontal direction of the substrate as the first direction and the vertical direction of the substrate as the second direction as an example to illustrate. Specifically, by arranging the first switch chip 40 in the second side area of the first transformer 12, wherein the second side area of the first transformer 12 is arranged along the second direction and is adjacent to the output end of the first transformer 12. For example, the output end of the first transformer 12 is arranged at the right side of the first transformer 12 in the vertical direction. The first switch chip 40 is arranged at the right side area of the first transformer 12 in the vertical direction. The second switch chip 50 is arranged in the second side area of the second transformer 22. The second side area of the second transformer 22 is arranged along the second direction and adjacent to the output end of the second transformer 22. For example, the output end of the second transformer 22 is arranged at the right side of the second transformer 22 in the vertical direction, and the second switch chip 50 is arranged at the right side area of the second transformer 22 in the vertical direction. In this way, it can be ensured that the first switch chip 40 and the output end of the first transformer are arranged close to each other, and the second switch chip 50 and the output end of the second transformer are set close to each other. Thereby optimizing the signal transmission paths between the first switch chip 40 and the first transformer and between the second switch chip 40 and the second transformer, reducing the redundancy and complexity of signal traces, avoiding unnecessary losses caused by excessively long traces, and meeting the requirements of RF front-end modules for performance and area.

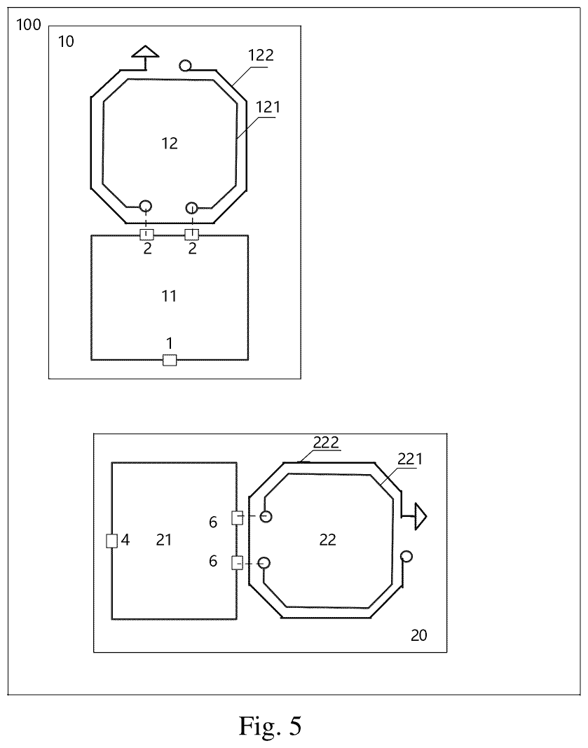

In a specific embodiment, as shown in FIG. 5 below, the first transformer 12 includes a first winding 121 and a second winding 122 coupled with each other, and the first winding 121 is connected with the first amplification chip 11. The first end of the second winding 121 is connected to the first switch chip, and the second end of the second winding 122 is connected to the ground. That is, the first end of the second winding 122 is the output end of the first transformer, and the first end of the second winding is arranged adjacent to the first switch chip. And/or, the second transformer 22 includes a third winding 221 and a fourth winding 222 coupled with each other, and the third winding 221 is connected with the second amplification chip 21. The first end of the fourth winding 222 is connected to the second switch chip, and the second end of the fourth winding 222 is connected to the ground. That is, the first end of the fourth winding is the output end of the second transformer, and the first end of the fourth winding is arranged adjacent to the second switch chip.

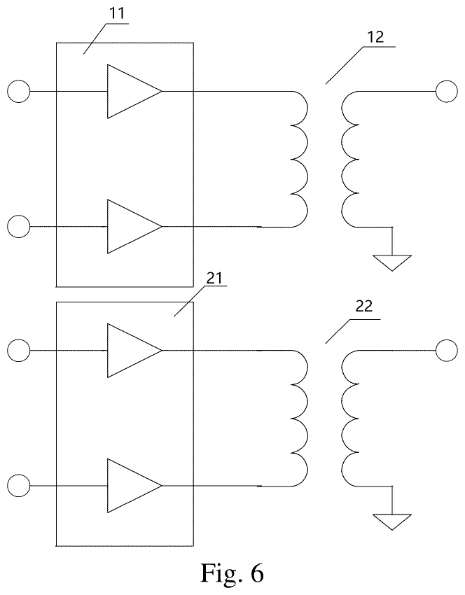

In a specific embodiment, as shown in FIG. 6 below, the first RF amplification circuit is the first differential amplification circuit and the second RF amplification circuit is the second differential amplification circuit.

In at least one embodiment, the first RF amplification circuit is a first differential amplification circuit. The first differential amplification circuit includes a first differential amplification transistor and a second differential amplification transistor. The first RF signal is amplified by the first differential amplification transistor and the second differential amplification transistor, and then two paths of first RF amplified signals are output to the first transformer for conversion and synthesis, and finally it is output through the first switch chip. The second RF amplification circuit is a second differential amplification circuit. The second differential amplification circuit includes a third differential amplification transistor and a fourth differential amplification transistor. The second RF signal is amplified by the third differential amplification transistor and the fourth differential amplification transistor, and then two paths of second RF amplified signals are output to the second transformer for conversion and synthesis, and finally it is output through the first switch chip.

In at least one embodiment, the RF front-end module further comprises a third transformer and a fourth transformer, the third transformer is connected with the first differential amplification circuit. The third transformer is configured to convert the first input signal into two paths of first RF signals with a phase difference of 180°, and input them into the first differential amplification transistor and the second differential amplification transistor for amplification. The fourth transformer is connected with the second differential amplification circuit. The fourth transformer is configured to convert the second input signal into two paths of second RF signals with a phase difference of 180°, and input them to the third differential amplification transistor and the fourth differential amplification transistor for amplification. The third transformer can be integrated with the first differential amplification circuit in the first amplification chip, or can be arranged on a substrate. The fourth transformer can be integrated with the second differential amplification circuit in the second amplification chip, or can be arranged on a substrate. This embodiment does not specifically limit the specific layout and implementation of the third transformer and the fourth transformer.

Preferably, in order to further address the problem of signal crosstalk between the first RF signal transmitted by the first power amplification unit and the second RF signal transmitted by the second power amplification unit, the layout similar to that of the first transformer and the second transformer described in the above embodiment may also by adopted for the third transformer and fourth transformer. That is, the spacing between the third transformer and the fourth transformer can be increased as much as possible. allowing mutual isolation degree to be improved. Therefore, while ensuring the integration and occupied area of the RF front-end module, the overall performance of the RF front-end module is optimized, and the quality of RF signals output by the RF front-end module is improved.

In this embodiment, the first RF amplification circuit is a first differential amplification circuit. The second RF amplification circuit is a second differential amplification circuit. By adopting two different amplification circuits for amplifying RF signals of different frequency bands, the power output efficiency of the RF front-end module can be improved.

In a specific embodiment, the RF signals of the first frequency band and the second frequency band are signals specified in the same mobile communication standard.

In at least one embodiment, the RF signals of the first frequency band and the second frequency band are signals specified in the same mobile communication standard. For example, the RF front-end module can simultaneously support the communication of signals in the frequency band specified by 4G and signals in another frequency band specified by 4G. That is, the RF signal in the first frequency band is the signal in the first frequency band specified by the fourth generation mobile communication standard; and the RF signal in the second frequency band is the signal in the second frequency band specified by the fourth generation mobile communication standard. Or, the RF front-end module can simultaneously support the communication of signals in the frequency band specified by 5G and the communication of signals in another frequency band specified by 5G. That is, the RF signal of the first frequency band is a signal of the first frequency band specified by the fifth generation mobile communication standard, and the RF signal of the second frequency band is a signal of the second frequency band specified by the fifth generation mobile communication standard.

The RF front-end module in this embodiment can alleviate the signal interference phenomenon when RF signals of two different frequency bands specified by the same mobile communication standard communicate simultaneously. For example, it can alleviate the signal interference phenomenon when the signals of the first frequency band specified in the fourth generation mobile communication standard/the fifth generation mobile communication standard and the signals of the second frequency band specified in the fourth generation mobile communication standard/the fifth generation mobile communication standard are simultaneously communicated.

In a specific embodiment, the first power amplification unit and the second power amplification unit are configured to support the transmission of dual-connectivity RF signals. That is, the first power amplification unit and the second power amplification unit are configured to work in the ENDC mode and support the transmission of the ENDCRF signal.

In at least one embodiment, when the RF front-end module is in the working state, the RF signal of the first frequency band can be transmitted through the first power amplification unit, and the RF signal of the second frequency band can be transmitted through the second power amplification unit. The RF front-end module can realize the combined transmission and dual-connectivity of the RF signal of the first frequency band and the RF signal of the second frequency band through the first power amplification unit and the second power amplification unit. ENDC technology is a dual-connectivity technology of LTE signal and 5G signal. The terminal can be connected with 4G base station and 5G base station at the same time, and support the transmission of LTE signal and 5G signal at the same time.

It can be understood that the first power amplification unit may be a unit for transmitting LTE signals or a unit for transmitting 5G signals. The RF signal of the first frequency band transmitted by the first antenna unit 110 may be an LTE signal. For example, the RF signal of the first frequency band may be, but is not limited to, a B1 frequency band signal, a B3 frequency band signal and a B7 frequency band signal. The RF signal of the second frequency band transmitted by the second power amplification unit may be a 5G signal. For example, the RF signal of the second frequency band may be, but not limited to, an N41 frequency band signal, an N78 frequency band signal and an N79 frequency band signal. Therefore, the RF front-end module is configured to support the transmission of LTE signals and the transmission of 5G signals.

In at least one embodiment, when the first power amplification unit and the second power amplification unit are configured to work in the ENDC mode, the signal crosstalk between the first power amplification unit and the second power amplification unit is quite noticeable, therefore, the first amplification chip 11 and the first transformer 12 in the first power amplification unit 10 are sequentially arranged along the first direction, and the second amplification chip 21 and the second transformer 22 are sequentially arranged along the second direction; wherein the first virtual straight line L1 extending along the first direction and the second virtual straight line L2 extending along the second direction intersect. That is, the first amplification chip 11 and the first transformer 12 are not arranged in parallel with the second amplification chip 21 and the second transformer 22 in the same direction, so as to allow the distance between the first transformer and the second transformer to be increased. This ameliorates the problem of signal crosstalk between the first RF signal transmitted by the first power amplification unit 10 and the second RF signal transmitted by the second power amplification unit 20, and further improves the isolation degree between the first power amplification unit 10 and the second power amplification unit 20 when working in the ENDC mode.

In a specific embodiment, the RF front-end module is configured to support the simultaneous transmission of RF signals by the first power amplification unit and the second power amplification unit.

In a specific embodiment, the RF front-end module is configured to support the simultaneous operation of the first power amplification unit and the second power amplification unit for simultaneous transmission of RF signals. Understandably, the working frequency band of the RF signal transmitted by the first power amplification unit and the working frequency band of the RF signal transmitted by the second power amplification unit may be the same or different.

In at least one embodiment, when the first power amplification unit and the second power amplification unit are configured to simultaneously transmit RF signals, the signal crosstalk between the first power amplification unit and the second power amplification unit is quite noticeable, therefore, the first amplification chip 11 and the first transformer 12 in the first power amplification unit 10 are sequentially arranged along the first direction, and the second amplification chip 21 and the second transformer 22 are sequentially arranged along the second direction; wherein the first virtual straight line L1 extending along the first direction and the second virtual straight line L2 extending along the second direction intersect. That is, the first amplification chip 11 and the first transformer 12 are not arranged in parallel with the second amplification chip 21 and the second transformer 22 in the same direction, so as to allow the distance between the first transformer and the second transformer to be increased. This ameliorates the problem of signal crosstalk between the first RF signal transmitted by the first power amplification unit 10 and the second RF signal transmitted by the second power amplification unit 20, and further improves the isolation degree between the first power amplification unit 10 and the second power amplification unit 20 when they simultaneously transmit RF signals.

This embodiment also provides an RF front-end module, which comprises a substrate, and a first power amplification unit and a second power amplification unit arranged on the substrate; the first power amplification unit comprises a first amplification chip and a first transformer connected with the first amplification chip; the second power amplification unit comprises a second amplification chip and a second transformer connected with the second amplification chip; the first transformer is arranged adjacent to the first side edge of the first amplification chip; wherein the extension direction of the first side edge of the first amplification chip is the first direction; the second transformer is arranged adjacent to the second side edge of the second amplification chip, wherein the extension direction of the second side edge of the second amplification chip is the second direction. The first direction and the second direction intersect; and the first power amplification unit and the second power amplification unit are configured to support transmission of dual-connectivity RF signals.

In at least one embodiment, the RF front-end module is configured to work in ENDC mode and support the transmission of ENDCRF signal. When the RF front-end module is in working state, the RF signal of the first frequency band can be transmitted through the first power amplification unit, and the RF signal of the second frequency band can be transmitted through the second power amplification unit. The RF front-end module can realize the combined transmission and dual-connectivity of the RF signal of the first frequency band and the RF signal of the second frequency band through the first power amplification unit and the second power amplification unit. ENDC technology is a dual-connectivity technology of LTE signal and 5G signal. The terminal can be connected with 4G base station and 5G base station at the same time, and support the transmission of LTE signal and 5G signal at the same time.

It can be understood that the first power amplification unit may be a unit for transmitting LTE signals or a unit for transmitting 5G signals. The RF signal of the first frequency band transmitted by the first antenna unit 110 may be an LTE signal. For example, the RF signal of the first frequency band may be, but is not limited to, a B1 frequency band signal, a B3 frequency band signal and a B7 frequency band signal. The RF signal of the second frequency band transmitted by the second power amplification unit may be a 5G signal. For example, the RF signal of the second frequency band may be, but not limited to, an N41 frequency band signal, an N78 frequency band signal and an N79 frequency band signal. Therefore, the RF front-end module is configured to support the transmission of LTE signals and the transmission of 5G signals.

In at least one embodiment, when the first power amplification unit and the second power amplification unit are configured to work in the ENDC mode, the signal crosstalk between the first power amplification unit and the second power amplification unit is quite noticeable, therefore, by arranging the first transformer adjacent to the first side edge of the first amplification chip (the extension direction of the first side edge of the first amplification chip is the first direction), and arranging the second transformer adjacent to the second side edge of the second amplification chip (the extension direction of the second side edge of the second amplification chip is the second direction), wherein the first direction and the second direction intersect, the spacing between the first transformer and the second transformer can be increased. This ameliorates the problem of signal crosstalk between the first RF signal transmitted by the first power amplification unit 10 and the second RF signal transmitted by the second power amplification unit 20, and further improves the isolation degree between the first power amplification unit 10 and the second power amplification unit 20 when working in the ENDC mode.

This embodiment also provides a communication device, including but not limited to a portable phone (e.g., a smart phone) or a wearable terminal (e.g., a smart watch).

For the description of this application, such as in the specification and claims, some terms are used to refer to specific components. It should be understood by those skilled in the art that hardware manufacturers may use different terms to refer to the same component. The specification and claims do not distinguish components by the difference of names, but by the difference of functions of components. As mentioned in the specification and claims, “comprise” and “include” are used as open-ended clauses, it shall be interpreted as “including but not limited to”. The term “basically” means that those skilled in the art can solve technical problems within a certain error range and basically achieve the expected technical effects.

For the description of this application, it should be understood that the terms “up”, “down”, “front”, “back”, “left”, “right” and “inside” and the like are based on the orientations or positional relationships shown in the attached drawings, only for convenience of describing the present invention and simplifying the description, and do not indicate or imply that the said device or element must have a specific orientation, be constructed or operated in a particular orientation, and therefore cannot be understood as a limitation of the present invention.

For the description of the present application, unless otherwise stated, “multiple” means two or more. For the description of the present application, it should be noted that unless otherwise specified and defined, the terms “installation”, “connected with” and “connected to” should be understood in a broad sense. For example, they may be fixedly connected, detachably connected or integrally connected, or may be mechanically connected or electrically connected, or may be directly connected or indirectly connected through an intermediate medium. Or it may be internal communication of two elements. For those of ordinary skill in the art, the specific meanings of the above terms in the present application may be understood in specific situations.

The terms “one embodiment”, “some embodiments”, “examples”, “specific examples”, or “some examples” in the specification refer to the fact that at least one embodiment or example of the embodiment of this application includes particular features, structures, materials, or characteristics that are described in connection with this embodiment or example. In this specification, the illustrative expressions of the above terms do not necessarily refer to the same embodiment or example. Furthermore, the specific features, structures, materials, or characteristics described may be combined in any one or more embodiments or examples in an appropriate manner. In addition, without contradicting one another, those skilled in the art may combine various embodiments, examples, and features of various embodiments, examples, and examples described in this specification.

Furthermore, the terms “first” and “second” are used for descriptive purposes only and cannot be understood as indicating or implying relative importance or implicitly indicating the number of technical features indicated. Thus, a feature defined by “first” or “second” may explicitly or implicitly includes one or more of the features. For the description of the present invention, “plurality” means at least two, such as two, three, etc., unless otherwise specifically defined.

The above embodiments are merely used to illustrate the technical solutions of the present application, rather than limit it. Although the application has been described in detail with reference to the foregoing embodiments, it should be understood by those skilled in the art that it is still possible to modify the technical solutions described in the foregoing embodiments, or equivalently replace some technical features thereof. These modifications and equivalents do not make the nature of the corresponding technical solution deviates from the spirit and scope of the present application. and shall be included in the protection scope of the present application.

What is claimed is:

1. An RF front-end module, comprising:
a substrate, and a first power amplification unit and a second power amplification unit arranged on the substrate; wherein
the first power amplification unit comprises a first amplification chip and a first transformer connected with the first amplification chip;
the second power amplification unit comprises a second amplification chip and a second transformer connected with the second amplification chip;
the first amplification chip and the first transformer are sequentially arranged along a first direction, and the second amplification chip and the second transformer are sequentially arranged along a second direction; and
a first virtual straight line extending along the first direction and a second virtual straight line extending along the second direction intersect each other.

2. The RF front-end module of claim 1, wherein the first virtual straight line and the second virtual straight line intersect at point O, and an angle range formed by a first virtual straight line segment extending along the first direction at point O and a second virtual straight line segment extending along the second direction at point O is [90°, 180°].

3. The RF front-end module of claim 1, wherein the first virtual straight line and the second virtual straight line intersect at an angle of 90°.

4. The RF front-end module of claim 1, wherein the first transformer is arranged adjacent to a first side edge of the first amplification chip, and an extension direction of the first side edge of the first amplification chip is the first direction; the second transformer is arranged adjacent to a second side edge of the second amplification chip, and an extension direction of the second side edge of the second amplification chip is the second direction;
the first direction and the second direction intersect.

5. The RF front-end module of claim 1, wherein the first transformer is arranged on a side of the first amplification chip away from the second power amplification unit, and/or, the second transformer is arranged on a side of the second amplification chip away from the first power amplification unit.

6. The RF front-end module of claim 1, wherein the RF front-end module further comprises a control chip, and the control chip is arranged between the first amplification chip and the second amplification chip.

7. The RF front-end module of claim 1, wherein the first amplification chip comprises a first RF amplification circuit, and the first RF amplification circuit is used for amplifying an RF signal of a first frequency band; the second amplification chip comprises a second RF amplification circuit, and the second RF amplification circuit is used for amplifying an RF signal of a second frequency band; the first frequency band and the second frequency band are different frequency bands.

8. The RF front-end module of claim 7, wherein the substrate comprises M first signal input ends and N second signal input ends, the M first signal inputs end and the N second signal input ends are arranged on a fourth side edge of the substrate, and the fourth side edge is arranged along the second direction; the first signal input end is used for inputting the RF signal of the first frequency band, and the second signal input end is used for inputting the RF signal of the second frequency band; the first amplification chip is arranged in an area close to the first signal input end, and the second amplification chip is arranged in an area close to the second signal input end.

9. The RF front-end module of claim 1, wherein the first amplification chip comprises a first output pin, the first output pin is connected with the first transformer and arranged on the first side edge of the first amplification chip, and the first side edge of the first amplification chip is arranged along the first direction and adjacent to the first transformer;
the second amplification chip comprises a second output pin, the second output pin is connected with the second transformer and arranged on the second side edge of the second amplification chip, and the second side edge of the second amplification chip is arranged along the second direction and adjacent to the second transformer.

10. The RF front-end module of claim 8, wherein the first amplification chip comprises a first input pin, and the first input pin is arranged on a third side edge of the first amplification chip, and the third side edge of the first amplification chip is arranged along the first direction and adjacent to the second amplification chip; the second amplification chip comprises a second input pin, the second input pin is arranged on a fourth side edge of the second amplification chip, and the fourth side edge of the second amplification chip is arranged along the second direction and adjacent to the second signal input end.

11. The RF front-end module of claim 1, wherein the RF front-end module further comprises a first switch chip and a second switch chip, and the first switch chip is connected with an output end of the first transformer, the second switch chip is connected with an output end of the second transformer; the first switch chip is arranged in a second side area of the first transformer, and the second side area of the first transformer is arranged along the second direction and adjacent to the output end of the first transformer; the second switch chip is arranged in a second side area of the second transformer, and the second side area of the second transformer is arranged along the second direction and adjacent to the output end of the second transformer.

12. The RF front-end module of claim 1, wherein:
the first transformer comprises a first winding and a second winding coupled with each other, the first winding is connected with the first RF amplification circuit, a first end of the second winding is connected with a first signal output end, and a second end of the second winding is connected to ground; and
the second transformer comprises a third winding and a fourth winding coupled with each other, the third winding is connected with the second RF amplification circuit, a first end of the fourth winding is connected with a second signal output end, and a second end of the fourth winding is connected to ground.

13. The RF front-end module of claim 7, wherein the first RF amplification circuit is a first differential amplification circuit, and the second RF amplification circuit is a second differential amplification circuit.

14. The RF front-end module of claim 7, wherein the RF signal of the first frequency band and the RF signal of the second frequency band are signals specified in a same mobile communication standard.

15. The RF front-end module of claim 1, wherein:
the first power amplification unit and the second power amplification unit are configured to support transmission of dual-connectivity RF signals; or
the RF front-end module is configured to support simultaneous transmission of RF signals by the first power amplification unit and the second power amplification unit.

16. The RF front-end module of claim 1, wherein the angle range formed by the intersection of the first virtual straight line and the second virtual straight line is at least one of [90°, 120°], (120°, 130°], (130°, 150°], (150°, 160°], (160°, 175°] or (175°, 180°].

17. An RF front-end module, comprising:
a substrate, and a first power amplification unit and a second power amplification unit arranged on the substrate; wherein
the first power amplification unit comprises a first amplification chip and a first transformer connected with the first amplification chip;
the second power amplification unit comprises a second amplification chip and a second transformer connected with the second amplification chip;
the first transformer is arranged adjacent to a first side edge of the first amplification chip, and an extension direction of the first side edge of the first amplification chip is a first direction; the second transformer is arranged adjacent to a second side edge of the second amplification chip, and an extension direction of the second side edge of the second amplification chip is a second direction; the first direction and the second direction intersect each other; and
the first power amplification unit and the second power amplification unit are configured to support transmission of dual-connectivity RF signals.

18. An RF front-end module, comprising:
a substrate, and a first power amplification unit and a second power amplification unit arranged on the substrate; wherein
the first power amplification unit comprises a first RF amplification circuit, a first transformer connected with an output end of the first RF amplification circuit, and a third transformer connected with an input end of the first RF amplification circuit;
the second power amplification unit comprises a second RF amplification circuit, a second transformer connected with an output end of the second RF amplification circuit, and a fourth transformer connected with an input end of the first RF amplification circuit; and
the third transformer, the first RF amplification circuit and the first transformer are sequentially arranged along a first direction; the fourth transformer, the second RF amplification circuit and the second transformer are sequentially arranged along a second direction; the first direction and the second direction intersect each other.

19. The RF front-end module of claim 18, wherein the third transformer is arranged near the second power amplification unit relative to the first RF amplification circuit, and the first transformer is arranged away from the second power amplification unit relative to the first RF amplification circuit; the fourth transformer is arranged near the first power amplification unit relative to the second RF amplification circuit, and the second transformer is arranged away from the first power amplification unit relative to the second RF amplification circuit.

20. The RF front-end module of claim 18, wherein the third transformer and the first RF amplification circuit are integrated on a first amplification chip, and the first transformer is arranged on the substrate; the fourth transformer and the second RF amplification circuit are integrated on a second amplification chip, and the second transformer is arranged on the substrate; or
the first transformer and the third transformer are arranged on the substrate, and the first RF amplification circuit is integrated on a first amplification chip; the second transformer and the fourth transformer are arranged on the substrate, and the second RF amplification circuit is integrated on a second amplification chip.
